(19) United States
(12) Patent Application Publication
(10) Pub. No.: US 2026/0255910 A1
(43) Pub. Date: Aug. 27, 2026

(54) COOLING SYSTEM FOR SEMICONDUCTOR MANUFACTURING PROCESS, AND SEMICONDUCTOR MANUFACTURING SYSTEM

(71) Applicant: EBARA CORPORATION, Tokyo (JP)

(72) Inventor: Yukihiro FUKUSUMI, Tokyo (JP)

(73) Assignee: EBARA CORPORATION, Tokyo (JP)

(21) Appl. No.: 19/159,562

(22) PCT Filed: Feb. 19, 2024
(86) PCT No.: PCT/JP2024/005720

§ 371 Date: Aug. 25, 2025

(30) Foreign Application Priority Data
Mar. 3, 2023 (JP) 2023-032484

(51) Int. Cl. H10P 72/00; F25B 25/00; F25D 17/02; H10P 50/20

(52) U.S. Cl. CPC H10P 72/0432; F25B 25/005; F25D 17/02; H10P 50/20; H10P 72/0448; H10P 72/0602

(57) ABSTRACT

The present invention relates to a cooling system for use in cooling of semiconductor manufacturing equipment, such as etching equipment. The cooling system (5) includes: at least one heat-exchanging unit (8) configured to generate a cooling liquid for cooling the multiple processing chambers (2A to 2C) arranged in a clean room and supply the cooling liquid to the multiple processing chambers (2A to 2C); a cooling apparatus (10) configured to cool an antifreeze liquid; an antifreeze-liquid circulation line (25) extending between the heat-exchanging unit (8) and the cooling apparatus (10); and an antifreeze-liquid pump (27) configured to circulate the antifreeze liquid, wherein the heat-exchanging unit (8) includes: a cooling-liquid pump (30) configured to circulate the cooling liquid; a heat exchanger (31) configured to perform heat exchange between the cooling liquid and the antifreeze liquid; and a cooling-side buffer tank (33) arranged upstream of the heat exchanger (31) in a circulating direction of the cooling liquid.

### TECHNICAL FIELD

The present invention relates to a cooling system for use in cooling of semiconductor manufacturing equipment, such as etching equipment.

### BACKGROUND ART

In a dry etching process, which is one of semiconductor manufacturing processes, etching equipment arranged in a clean room is used. A cooling system for cooling a circulating liquid flowing through multiple processing chambers of the etching equipment is mainly arranged in a sub-fab area located downstairs under the clean room. Unlike environments (e.g., a machine room) in which general equipment and machinery are installed, high cleanliness is required in the clean room and the sub-fab area. FIG. 11 is a schematic diagram showing a cooling system for cooling multiple processing chambers. As shown in FIG. 11, etching equipment 501 has multiple processing chambers 502. The etching equipment 501 is configured to perform an etching process on a wafer in each processing chamber 502.

The multiple processing chambers 502 are coupled to multiple chillers 505, respectively, and the number of chillers 505 is the same as the number of processing chambers 502. These chillers 505 operate independently and supply a circulating liquid for cooling the multiple processing chambers 502 to the multiple processing chambers 502, respectively. Each chiller 505 includes a refrigeration cycle having an evaporator 506, a compressor 507, and a condenser 508. A refrigerant circulates in each refrigeration cycle. In the refrigeration cycle of each chiller 505, heat exchange is performed, in the condenser 508, between the refrigerant and a cooling liquid generated by a large refrigeration machine 510, and heat exchange is performed, in the evaporator 506, between the refrigerant and the circulating liquid for cooling each processing chamber 502. The circulating liquid cooled by the heat exchange with the refrigerant cools each processing chamber 502 while passing through each multiple processing chamber 502.

### CITATION LIST

### Patent Literature

Patent document 1: Japanese laid-open patent publication No. 2021-81145

Patent document 2: Japanese laid-open patent publication No. 2021-77085

Patent document 3: Japanese laid-open patent publication No. 2022-174869

### SUMMARY OF INVENTION

### Technical Problem

The multiple chillers 505 are arranged in the sub-fab area, and the large refrigeration machine 510 is arranged in a machine room located outside the clean room and the sub-fab area. In recent years, the number of processing chambers in the etching equipment tends to increase, and the number of chillers corresponding to these processing chambers also tends to increase. However, since the sub-fab area needs to be provided directly below the clean room, there is a limit to the size of the sub-fab area. As a result, there has been a problem that a space for the increased number of chillers cannot be provided in the sub-fab area. In addition, the increase in the number of chillers entails an increase in power consumption of the entire cooling system.

Therefore, the present invention provides a cooling system that does not require a large installation space, is capable of cooling multiple processing chambers for use in semiconductor manufacturing equipment, and is capable of reducing power consumption of the entire cooling system.

### Solution to Problem

In an embodiment, there is provided a cooling system for cooling multiple processing chambers for use in semiconductor manufacturing process, comprising: at least one heat-exchanging unit configured to generate a cooling liquid for cooling the multiple processing chambers arranged in a clean room and supply the cooling liquid to the multiple processing chambers; a cooling apparatus configured to cool an antifreeze liquid; an antifreeze-liquid circulation line extending between the heat-exchanging unit and the cooling apparatus; and an antifreeze-liquid pump configured to circulate the antifreeze liquid in the antifreeze-liquid circulation line, wherein the heat-exchanging unit includes: a cooling-liquid pump configured to circulate the cooling liquid through the multiple processing chambers; a heat exchanger configured to perform heat exchange between the cooling liquid and the antifreeze liquid; and a cooling-side buffer tank arranged upstream of the heat exchanger in a circulating direction of the cooling liquid.

According to the present invention, each of the heat-exchanging units does not have components, such as an evaporator, a compressor, and a condenser, unlike a refrigeration cycle of each of conventional chillers. Therefore, the heat-exchanging units do not require a large installation space in a sub-fab area, and are capable of cooling the multiple processing chambers for use in semiconductor manufacturing equipment.

Furthermore, according to the present invention, high cooling efficiency can be achieved by comprehensively generating the antifreeze liquid in the cooling apparatus, the antifreeze liquid having a sufficiently low temperature for generating the cooling liquid to be supplied to the multiple processing chambers. As a result, power consumption of the cooling apparatus is smaller than a total power consumption of the conventional chillers, so that energy-saving operation can be achieved.

In an embodiment, the cooling apparatus includes: a first refrigeration apparatus configured to circulate a first refrigerant for performing heat exchange with the antifreeze liquid; a second refrigeration apparatus configured to circulate a second refrigerant for performing heat exchange with the first refrigerant; and an intermediate-medium circulation line configured to circulate an intermediate medium between the first refrigeration apparatus and the second refrigeration apparatus.

According to the present invention, the cooling apparatus including the first refrigeration apparatus and the second refrigeration apparatus comprehensively cools the multiple processing chambers, and has a function equivalent to that of a cooling apparatus including a dual refrigeration cycle by coupling the first refrigeration apparatus and the second refrigeration apparatus in series. Therefore, the antifreeze liquid can be cooled to a sufficiently low temperature. In addition, since the first refrigeration apparatus and the second refrigeration apparatus are configured as separate apparatuses, the first refrigeration apparatus and the second refrigeration apparatus can be installed in different locations.

In an embodiment, the cooling apparatus comprises a refrigeration machine including a dual refrigeration cycle.

According to the present invention, the cooling apparatus including the dual refrigeration cycle can cool the antifreeze liquid to a sufficiently low temperature required for comprehensively cooling the multiple processing chambers by itself.

In an embodiment, the heat-exchanging unit is arranged in a sub-fab area located under the clean room.

According to the present invention, the heat-exchanging unit is arranged in the sub-fab area located under the clean room, so that an installation area in the clean room can be reduced.

In an embodiment, the first refrigeration apparatus is arranged in a sub-fab area located under the clean room, and the second refrigeration apparatus is arranged outside the clean room and the sub-fab area.

According to the present invention, a pipe extending to the heat-exchanging unit can be shortened by arranging the first refrigeration apparatus in the sub-fab area, so that heat loss can be reduced.

Furthermore, the second refrigeration apparatus is arranged outside the clean room and the sub-fab area, so that an installation space required in the clean room and the sub-fab area can be reduced.

In an embodiment, the first refrigeration apparatus comprises a turbo refrigeration machine including a compressor configured to compress refrigerant gas, and the compressor includes: an impeller; a rotor rotatable together with the impeller; and a magnetic bearing configured to rotatably support the rotor in a non-contact manner.

According to the present invention, the turbo refrigeration machine using the magnetic bearing in the compressor does not use lubricating oil and operates with low noise, so that the turbo refrigeration machine can be arranged in the sub-fab area where high cleanliness is required.

In an embodiment, the cooling apparatus comprises a turbo refrigeration machine including a compressor configured to compress refrigerant gas, and the compressor includes: an impeller; a rotor rotatable together with the impeller; and a magnetic bearing configured to rotatably support the rotor in a non-contact manner.

According to the present invention, the turbo refrigeration machine includes a centrifugal compressor in which the magnetic bearing is used, so that a larger capacity and a higher efficiency than a conventional chiller including a positive displacement compressor can be achieved. In addition, the magnetic bearing is used in the compressor, so that oil-free is achieved and recovery of oil is not required, and as a result, the efficiency can be further improved. Therefore, the cooling apparatus can cool the antifreeze liquid to a sufficiently low temperature required for comprehensively cooling the multiple processing chambers by itself.

In an embodiment, the cooling apparatus is arranged outside the clean room and a sub-fab area located under the clean room.

According to the present invention, the cooling apparatus is arranged outside the clean room and the sub-fab area, so that an installation space required in the clean room and the sub-fab area can be reduced.

In an embodiment, the heat-exchanging unit is removable from the cooling system.

According to the present invention, the heat-exchanging unit can be easily removed to perform maintenance, repair, etc. Furthermore, the heat-exchanging unit can be easily replaced with a new unit having modified specifications.

In an embodiment, the at least one heat-exchanging unit comprises multiple heat-exchanging units, and the number of multiple heat-exchanging units is the same as the number of multiple processing chambers.

According to the present invention, the multiple heat-exchanging units can operate independently according to processing cycles in the multiple processing chambers.

In an embodiment, the at least one heat-exchanging unit comprises multiple heat-exchanging units, and the number of multiple heat-exchanging units is less than the number of multiple processing chambers.

According to the present invention, an installation space required for the heat-exchanging units themselves can be reduced, and the number of pipes coupled to the heat-exchanging units can also be reduced. As a result, the installation space required in the sub-fab area can be further reduced.

In an embodiment, the at least one heat-exchanging unit comprises a single heat-exchanging unit.

According to the present invention, an installation space required for the heat-exchanging unit itself can be reduced, and the number of pipes coupled to the heat-exchanging unit can also be reduced. As a result, the installation space required in the sub-fab area can be further reduced.

In addition, since the single cooling-side buffer tank is provided, even if variations in temperature of the cooling liquid returned from the processing chambers occur, the cooling-side buffer tank functions as a thermal buffer to make the temperature of the cooling liquid uniform. As a result, heat exchange conditions in the heat-exchanging unit can be improved.

In an embodiment, the cooling system further comprises: at least one heating unit configured to generate a heating liquid for heating the multiple processing chambers and supply the heating liquid to the multiple processing chambers, wherein the heating unit includes: a heating apparatus configured to heat the heating liquid; a heating-liquid pump configured to circulate the heating liquid through the multiple processing chambers; and a heating-side buffer tank arranged upstream of the heating apparatus in a circulating direction of the heating liquid.

According to the present invention, the cooling system can not only cool the processing chambers but also heat the processing chambers.

In an embodiment, the heating unit is removable from the cooling system.

According to the present invention, the heating unit can be easily removed to perform maintenance, repair, etc. Furthermore, the heating unit can be easily replaced with a new unit having modified specifications.

In an embodiment, the at least one heating unit comprises multiple heating units, and the number of multiple heating units is the same as the number of multiple processing chambers.

According to the present invention, the multiple heating units can operate independently according to processing cycles in the multiple processing chambers.

In an embodiment, the at least one heating unit comprises multiple heating units, and the number of multiple heating units is less than the number of multiple processing chambers.

According to the present invention, an installation space required for the heating units themselves can be reduced, and the number of pipes coupled to the heating units can also be reduced. As a result, the installation space required in the sub-fab area can be further reduced.

In addition, a time required to heat each processing chamber during the processing cycle performed in the processing chamber is relatively short. Therefore, the heating apparatus with a low heating capacity (i.e., low power consumption) can be used to heat the multiple processing chambers by adjusting the processing cycles of the processing chambers so as not to overlap the heating times of the multiple processing chambers.

In an embodiment, the at least one heating unit comprises a single heating unit.

According to the present invention, an installation space required for the heating unit itself can be reduced, and the number of pipes coupled to the heating unit can also be reduced. As a result, the installation space required in the sub-fab area can be further reduced.

In addition, a time required to heat each processing chamber during the processing cycle performed in the processing chamber is relatively short. Therefore, the heating apparatus with a low heating capacity (i.e., low power consumption) can be used to heat the multiple processing chambers by adjusting the processing cycles of the processing chambers so as not to overlap the heating times of the multiple processing chambers.

Furthermore, since the single heating-side buffer tank is provided, even if variations in temperature of the heating liquid returned from the processing chambers occur, the heating-side buffer tank functions as a thermal buffer to make the temperature of the heating liquid uniform. As a result, fluctuations in the temperature of the heated liquid flowing through the heating apparatus can be reduced.

In an embodiment, there is provided a semiconductor manufacturing system comprising: semiconductor manufacturing equipment having multiple processing chambers for performing a semiconductor manufacturing process; a temperature regulator configured to regulate temperature of the multiple processing chambers; a cooling-liquid line extending between the temperature regulator and the heat-exchanging unit; a temperature-regulating-liquid line extending between the temperature regulator and the multiple processing chambers; and the above-mentioned cooling system for cooling the multiple processing chambers.

### Advantageous Effects of Invention

According to the present invention, the heat-exchanging unit(s) does not have components, such as a compressor, a condenser, and an evaporator, unlike a refrigeration cycle of each of conventional chillers. Therefore, the heat-exchanging unit(s) does not require a large installation space in a sub-fab area, and is capable of cooling the multiple processing chambers for use in the semiconductor manufacturing equipment.

Furthermore, according to the present invention, high cooling efficiency can be achieved by comprehensively generating the antifreeze liquid in the cooling apparatus, the antifreeze liquid having a sufficiently low temperature for generating the cooling liquid to be supplied to the multiple processing chambers. As a result, power consumption of the cooling apparatus is smaller than a total power consumption of the conventional chillers, so that energy-saving operation can be achieved.

### BRIEF DESCRIPTION OF DRAWINGS

FIG. 1 is a schematic diagram showing an embodiment of a semiconductor manufacturing system including a cooling system;

FIG. 2 is a schematic diagram showing an embodiment of a detailed structure of a cooling apparatus;

FIG. 3 is a schematic diagram showing an embodiment of a detailed structure of a first compressor of a first refrigeration apparatus;

FIG. 4 is a schematic diagram showing another embodiment of a detailed structure of the cooling apparatus;

FIG. 5 is a schematic diagram showing another embodiment of the semiconductor manufacturing system including the cooling system;

FIG. 6 is a schematic diagram showing an embodiment of a detailed structure of the cooling apparatus shown in FIG. 5;

FIG. 7 is a schematic diagram showing still another embodiment of the semiconductor manufacturing system including the cooling system;

FIG. 8 is a schematic diagram showing still another embodiment of the semiconductor manufacturing system including the cooling system;

FIG. 9 is a schematic diagram showing still another embodiment of the semiconductor manufacturing system including the cooling system;

FIG. 10 is a schematic diagram showing still another embodiment of the semiconductor manufacturing system including the cooling system; and

FIG. 11 is a schematic diagram showing a conventional cooling system.

### DESCRIPTION OF EMBODIMENTS

Hereinafter, embodiments of the present invention will be described with reference to the drawings.

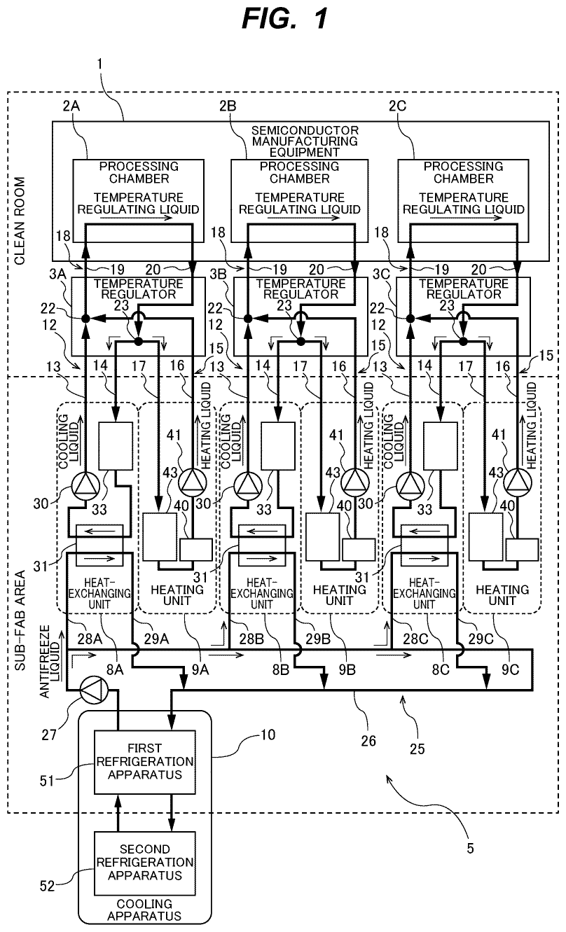

FIG. 1 is a schematic diagram showing an embodiment of a semiconductor manufacturing system including a cooling system 5. The semiconductor manufacturing system includes semiconductor manufacturing equipment 1 having multiple (three in this embodiment) processing chambers 2A to 2C configured to perform a semiconductor manufacturing process, multiple (three in this embodiment) temperature regulators 3A to 3C configured to regulate temperatures of the multiple processing chambers 2A to 2C, and a cooling system 5 configured to cool the multiple processing chambers 2A to 2C. The semiconductor manufacturing equipment 1 and the temperature regulators 3A to 3C are arranged in a clean room.

The semiconductor manufacturing equipment 1 of this embodiment is etching equipment configured to perform an etching process. In one embodiment, the semiconductor manufacturing equipment 1 may be equipment configured to perform other process, such as CVD equipment or PVD equipment. In this embodiment, the semiconductor manufacturing equipment 1 has three processing chambers 2A to 2C, but in one embodiment, the semiconductor manufacturing equipment 1 may have two processing chambers, or four or more processing chambers. The semiconductor manufacturing system includes multiple temperature regulators, the number of which corresponds to the number of processing chambers. The temperature regulators 3A to 3C are coupled to the processing chambers 2A to 2C, respectively. The temperature regulators 3A to 3C are configured to generate temperature-regulating liquids that regulate the temperatures of the processing chambers 2A to 2C, respectively. Therefore, the temperature regulators 3A to 3C can regulate the temperatures of the processing chambers 2A to 2C individually.

The cooling system 5 is coupled to the three processing chambers 2A to 2C via the three temperature regulators 3A to 3C. The cooling system 5 includes multiple (three in this embodiment) heat-exchanging units 8A to 8C configured to generate a cooling liquid for cooling the three processing chambers 2A to 2C, multiple (three in this embodiment) heating units 9A to 9C configured to generate a heating liquid for heating the three processing chambers 2A to 2C, and a cooling apparatus 10 configured to cool an antifreeze liquid.

In this embodiment, the number of heat-exchanging units 8A to 8C is the same as the number of processing chambers 2A to 2C, and the number of heating units 9A to 9C is the same as the number of processing chambers 2A to 2C. In one embodiment, the number of heat-exchanging units 8A to 8C may be less than the number of processing chambers 2A to 2C, and the number of heating units 9A to 9C may be less than the number of processing chambers 2A to 2C.

At least a part of the cooling system 5 is arranged in a sub-fab area. In this embodiment, the heat-exchanging units 8A to 8C, the heating units 9A to 9C, and a part of the cooling apparatus 10 are arranged in the sub-fab area. The cooling liquid and the heating liquid are the same type of liquid, such as a fluorine-based inert liquid. The heat-exchanging units 8A to 8C and the heating units 9A to 9C are installed in the sub-fab area located under the clean room, so that an installation area in the clean room can be reduced.

The semiconductor manufacturing system further includes three cooling-liquid lines 12 extending between the three temperature regulators 3A to 3C and the three heat-exchanging units 8A to 8C, respectively, three heating-liquid lines 15 extending between the three temperature regulators 3A to 3C and the three heating units 9A to 9C, respectively, and three temperature-regulating-liquid lines 18 extending between the three temperature regulators 3A to 3C and the three processing chambers 2A to 2C, respectively. The three cooling-liquid lines 12 have basically the same configuration, the three heating-liquid lines 15 have basically the same configuration, and the three temperature-regulating-liquid lines 18 have basically the same configuration. The cooling-liquid line 12 extending between the temperature regulator 3A and the heat-exchanging unit 8A, the heating-liquid line 15 extending between the temperature regulator 3A and the heating unit 9A, and the temperature-regulating-liquid line 18 extending between the temperature regulator 3A and the processing chamber 2A will be described below. The three temperature regulators 3A to 3C basically have the same configuration, and duplicated descriptions will be omitted.

The cooling-liquid line 12 extending between the temperature regulator 3A and the heat-exchanging unit 8A includes a cooling-liquid supply line 13 configured to supply the cooling liquid generated by the heat-exchanging unit 8A to the temperature regulator 3A, and a cooling-liquid return line 14 configured to return the cooling liquid that has passed through the processing chamber 2A and the temperature regulator 3A to the heat-exchanging unit 8A. The heating-liquid line 15 extending between the temperature regulator 3A and the heating unit 9A includes a heating-liquid supply line 16 configured to supply the heating liquid generated by the heating unit 9A to the temperature regulator 3A, and a heating-liquid return line 17 configured to return the heating liquid that has passed through the processing chamber 2A and the temperature regulator 3A to the heating unit 9A. The temperature-regulating-liquid line 18 extending between the temperature regulator 3A and the processing chamber 2A includes a temperature-regulating-liquid supply line 19 configured to supply the temperature-regulating liquid generated by the temperature regulator 3A to the processing chamber 2A, and a temperature-regulating-liquid return line 20 configured to return the temperature-regulating liquid that has passed through the processing chamber 2A to the temperature regulator 3A.

One end of the cooling-liquid supply line 13 is coupled to the heat-exchanging unit 8A, and one end of the heating-liquid supply line 16 is coupled to the heating unit 9A. The other end of the cooling-liquid supply line 13 and the other end of the heating-liquid supply line 16 are coupled to a mixing section 22 of the temperature regulator 3A. The cooling liquid generated by the heat-exchanging unit 8A and the heating liquid generated by the heating unit 9A flow through the cooling-liquid supply line 13 and the heating-liquid supply line 16, respectively, and are mixed in the mixing section 22 of the temperature regulator 3A to form the temperature-regulating liquid. The temperature of the temperature-regulating liquid to be delivered to the processing chamber 2A is determined by a flow rate of the cooling liquid and a flow rate of the heating liquid (i.e., a mixing ratio of the cooling liquid and the heating liquid). The temperature regulator 3A includes a cooling-liquid flow-rate regulating valve (not shown) and a heating-liquid flow-rate regulating valve (not shown). The flow rate of the cooling liquid and the flow rate of the heating liquid are regulated by the cooling-liquid flow-rate regulating valve and the heating-liquid flow-rate regulating valve, respectively, based on a target temperature of the processing chamber 2A. In this way, the temperature regulator 3A generates the temperature-regulating liquid for regulating the temperature of the processing chamber 2A.

In one embodiment, the flow rate of the cooling liquid may be set to 0 and only the heating liquid may be supplied to the processing chamber 2A. Similarly, the flow rate of the heating liquid may be set to 0 and only the cooling liquid may be supplied to the processing chamber 2A. The target temperature of the processing chamber 2A may be a temperature for cooling the processing chamber 2A or may be a temperature for heating the processing chamber 2A.

The mixing section 22 of the temperature regulator 3A is coupled to the processing chamber 2A via the temperature-regulating-liquid supply line 19. The temperature-regulating liquid generated by the temperature regulator 3A flows through the temperature-regulating-liquid supply line 19 and is supplied to the processing chamber 2A. The processing chamber 2A is coupled to a distribution section 23 of the temperature regulator 3A via the temperature-regulating-liquid return line 20. One end of the cooling-liquid return line 14 is coupled to the distribution section 23, and the other end of the cooling-liquid return line 14 is coupled to the heat-exchanging unit 8A. One end of the heating-liquid return line 17 is coupled to the distribution section 23, and the other end of the heating-liquid return line 17 is coupled to the heating unit 9A.

The temperature-regulating liquid that has passed through the processing chamber 2A flows through the temperature-regulating-liquid return line 20 and is distributed to the cooling-liquid return line 14 and the heating-liquid return line 17 at the distribution section 23 of the temperature regulator 3A. Specifically, a part of the temperature-regulating liquid is returned as the cooling liquid to the heat-exchanging unit 8A through the cooling-liquid return line 14, and the other part of the temperature-regulating liquid is returned as the heating liquid to the heating unit 9A through the heating-liquid return line 17. In this way, the cooling liquid circulates between the heat-exchanging unit 8A, the temperature regulator 3A, and the processing chamber 2A through the cooling-liquid line 12 and the temperature-regulating-liquid line 18. The heating liquid circulates between the heating unit 9A, the temperature regulator 3A, and the processing chamber 2A through the heating-liquid line 15 and the temperature-regulating-liquid line 18.

Similarly, the cooling liquid generated by the heat-exchanging unit 8B circulates between the heat-exchanging unit 8B, the temperature regulator 3B, and the processing chamber 2B. The heating liquid generated by the heating unit 9B circulates between the heating unit 9B, the temperature regulator 3B, and the processing chamber 2B. The cooling liquid generated by the heat-exchanging unit 8C circulates between the heat-exchanging unit 8C, the temperature regulator 3C, and the processing chamber 2C. The heating liquid generated by the heating unit 9C circulates between the heating unit 9C, the temperature regulator 3C, and the processing chamber 2C.

Next, configurations of the heat-exchanging units 8A to 8C will be described. The three heat-exchanging units 8A to 8C basically have the same configuration, and the heat-exchanging unit 8A will be described below. The heat-exchanging unit 8A includes a cooling-liquid pump 30 configured to circulate the cooling liquid through the processing chamber 2A, a heat exchanger 31 configured to perform heat exchange between the cooling liquid and the antifreeze liquid supplied from the cooling apparatus 10, and a cooling-side buffer tank 33 arranged upstream of the heat exchanger 31 in a circulating direction of the cooling liquid. The cooling-liquid supply line 13 is coupled to the heat exchanger 31 via the cooling-liquid pump 30, and the cooling-liquid return line 14 is coupled to the heat exchanger 31 via the cooling-side buffer tank 33. The cooling-liquid pump 30 is coupled to the cooling-liquid supply line 13, and is arranged downstream of the heat exchanger 31 in the circulating direction of the cooling liquid. In one embodiment, the cooling-liquid pump 30 may be arranged upstream of the heat exchanger 31 in the circulating direction of the cooling liquid. The cooling-side buffer tank 33 is coupled to the cooling-liquid return line 14 and the heat exchanger 31. The cooling-liquid pump 30 is configured to circulate the cooling liquid through the temperature regulator 3A, the processing chamber 2A, and the heat-exchanging unit 8A.

The cooling liquid returned to the heat-exchanging unit 8A through the cooling-liquid return line 14 is stored in the cooling-side buffer tank 33. The cooling-side buffer tank 33 functions as a thermal buffer, so that fluctuations in the temperature of the cooling liquid to be supplied to the heat exchanger 31 can be reduced. The cooling liquid flowing out from the cooling-side buffer tank 33 is introduced to the heat exchanger 31, and performs the heat exchange, in the heat exchanger 31, with the antifreeze liquid supplied from the cooling apparatus 10. As a result of the heat exchange between the cooling liquid and the antifreeze liquid, the cooling liquid is cooled, while the antifreeze liquid is heated. The cooling liquid cooled by passing through the heat exchanger 31 is supplied to the temperature regulator 3A through the cooling-liquid supply line 13 by the cooling-liquid pump 30, and is supplied to the processing chamber 2A through the temperature-regulating-liquid supply line 19. In this way, the heat-exchanging unit 8A supplies the cooling liquid to the processing chamber 2A via the temperature regulator 3A.

Similarly, the heat-exchanging unit 8B supplies the cooling liquid to the processing chamber 2B via the temperature regulator 3B, and the heat-exchanging unit 8C supplies the cooling liquid to the processing chamber 2C via the temperature regulator 3C. In this embodiment, the heat-exchanging units 8A to 8C are individually removable from the cooling system 5. Therefore, any one of the heat-exchanging units 8A to 8C can be removed for maintenance, repair, etc. Furthermore, each of the heat-exchanging units 8A to 8C can be easily replaced with a new unit having modified specifications. In one embodiment, the heat-exchanging units 8A to 8C may not be configured to be removable from the cooling system 5. For example, the heat-exchanging units 8A to 8C may be integrally constructed with the heating units 9A to 9C, respectively.

Next, configurations of the heating units 9A to 9C will be described. The three heating units 9A to 9C have basically the same configuration, and the heating unit 9A will be described below. The heating unit 9A includes a heating apparatus 40 configured to heat the heating liquid, a heating-liquid pump 41 configured to circulate the heating liquid through the processing chamber 2A, and a heating-side buffer tank 43 arranged upstream of the heating apparatus 40 in a circulating direction of the heating liquid. The heating-liquid supply line 16 is coupled to the heating apparatus 40 via the heating-liquid pump 41, and the heating-liquid return line 17 is coupled to the heating apparatus 40 via the heating-side buffer tank 43. The heating-liquid pump 41 is coupled to the heating-liquid supply line 16, and is arranged downstream of the heating apparatus 40 in the circulating direction of the heating liquid. In one embodiment, the heating-liquid pump 41 may be arranged upstream of the heating apparatus 40 in the circulating direction of the heating liquid. The heating-side buffer tank 43 is coupled to the heating-liquid return line 17 and the heating apparatus 40. The heating-liquid pump 41 is configured to circulate the heating liquid through the temperature regulator 3A, the processing chamber 2A, and the heating unit 9A.

The heating liquid returned to the heating unit 9A through the heating-liquid return line 17 is stored in the heating-side buffer tank 43. The heating-side buffer tank 43 functions as a thermal buffer, so that fluctuations in the temperature of the heating liquid flowing into the heating apparatus 40 can be reduced. The heating liquid flowing out from the heating-side buffer tank 43 is introduced to the heating apparatus 40, and is heated in the heating apparatus 40. The heating liquid heated in the heating apparatus 40 is supplied to the temperature regulator 3A through the heating-liquid supply line 16 by the heating-liquid pump 41, and is supplied to the processing chamber 2A through the temperature-regulating-liquid supply line 19. In this way, the heating unit 9A supplies the heating liquid to the processing chamber 2A through the temperature regulator 3A. An electric heater or the like can be used for the heating apparatus 40. The configuration of the heating apparatus 40 is not particularly limited as long as the heating apparatus 40 can heat the liquid.

Similarly, the heating unit 9B supplies the heating liquid to the processing chamber 2B via the temperature regulator 3B, and the heating unit 9C supplies the heating liquid to the processing chamber 2C via the temperature regulator 3C. In this embodiment, the heating units 9A to 9C are individually removable from the cooling system 5. Therefore, any one of the heating units 9A to 9C can be removed for maintenance, repair, etc. Furthermore, each of the heating units 9A to 9C can be easily replaced with a new unit having modified specifications. In one embodiment, the heating units 9A to 9C may not be configured to be removable from the cooling system 5. For example, the heating units 9A to 9C may be integrally constructed with the heat-exchanging units 8A to 8C, respectively.

The cooling system 5 further includes an antifreeze-liquid circulation line 25 extending between the three heat-exchanging units 8A to 8C and the cooling apparatus 10, and an antifreeze-liquid pump 27 configured to circulate the antifreeze liquid in the antifreeze-liquid circulation line 25. The antifreeze-liquid pump 27 is disposed in the antifreeze-liquid circulation line 25, and is configured to circulate the antifreeze liquid between the cooling apparatus 10 and the three heat-exchanging units 8A to 8C. The antifreeze liquid is, for example, a perfluorocarbon (PFC) liquid, an ethylene glycol liquid, or the like.

The antifreeze-liquid circulation line 25 includes a trunk circulation line 26 coupled to the cooling apparatus 10, and a first branch supply line 28A, a first branch return line 29A, a second branch supply line 28B, a second branch return line 29B, a third branch supply line 28C, and a third branch return line 29C, all of which branch off from the trunk circulation line 26. The first branch supply line 28A and the first branch return line 29A extend between the trunk circulation line 26 and the heat-exchanging unit 8A. The second branch supply line 28B and the second branch return line 29B extend between the trunk circulation line 26 and the heat-exchanging unit 8B. The third branch supply line 28C and the third branch return line 29C extend between the trunk circulation line 26 and the heat-exchanging unit 8C. The antifreeze-liquid pump 27 is disposed in the trunk circulation line 26 of the antifreeze-liquid circulation line 25.

The antifreeze liquid supplied from the cooling apparatus 10 flows through the trunk circulation line 26, and branches off into the first branch supply line 28A, the second branch supply line 28B, and the third branch supply line 28C. The antifreeze liquid flowing through the first branch supply line 28A is introduced to the heat exchanger 31 of the heat-exchanging unit 8A, and performs the heat exchange with the cooling liquid in the heat exchanger 31 as described above. The antifreeze liquid heated by passing through the heat exchanger 31 passes through the first branch return line 29A, and is merged into the trunk circulation line 26.

Similarly, the antifreeze liquid flowing through the second branch supply line 28B is introduced to the heat exchanger 31 of the heat-exchanging unit 8B, and performs the heat exchange with the cooling liquid in the heat exchanger 31. The antifreeze liquid heated by passing through the heat exchanger 31 passes through the second branch return line 29B, and is merged into the trunk circulation line 26. The antifreeze liquid flowing through the third branch supply line 28C is introduced to the heat exchanger 31 of the heat-exchanging unit 8C, and performs the heat exchange with the cooling liquid in the heat exchanger 31. The antifreeze liquid heated by passing through the heat exchanger 31 passes through the third branch return line 29C, and is merged into the trunk circulation line 26.

The antifreeze liquid that has passed through the heat-exchanging units 8A to 8C and has been merged into the trunk circulation line 26 is returned to the cooling apparatus 10. The first branch return line 29A, the second branch return line 29B, and the third branch return line 29C are coupled to the trunk circulation line 26 at a junction point. The junction point is located downstream of branch points where the first branch supply line 28A, the second branch supply line 28B, and the third branch supply line 28C branch off from the trunk circulation line 26 in a circulating direction of the antifreeze liquid.

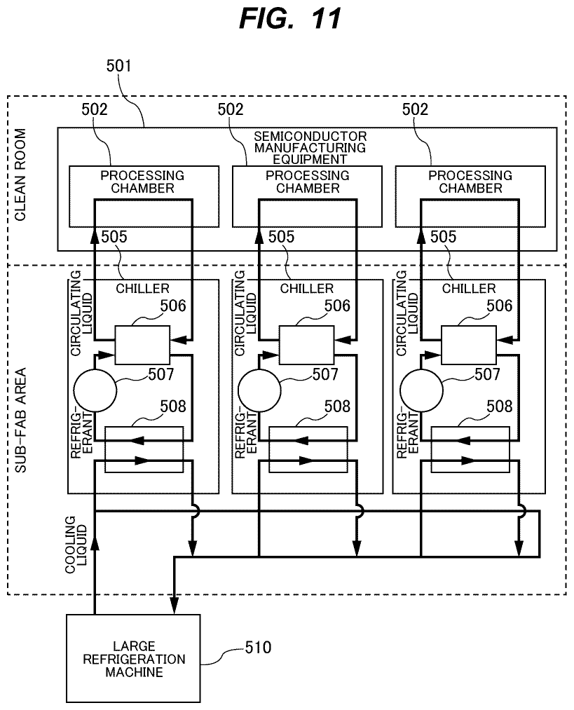

According to this embodiment, each of the heat-exchanging units 8A to 8C does not have components, such as a compressor, a condenser, or an evaporator, unlike the refrigeration cycle of each of the conventional chillers (see FIG. 11). Therefore, the heat-exchanging units 8A to 8C do not require a large installation space in the sub-fab area, and are capable of cooling the multiple processing chambers 2A to 2C for use in the semiconductor manufacturing equipment 1.

Furthermore, according to this embodiment, high cooling efficiency can be achieved by comprehensively generating the antifreeze liquid in the cooling apparatus 10, the antifreeze liquid having a sufficiently low temperature for generating the cooling liquid to be supplied to the multiple processing chambers 2A to 2C. As a result, power consumption of the cooling apparatus 10 is smaller than a total power consumption of the conventional chillers, so that energy-saving operation can be achieved.

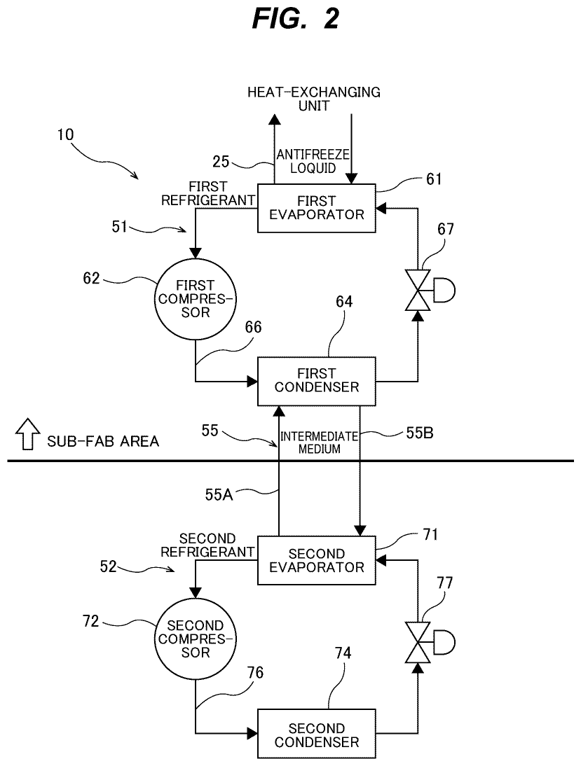

Next, a configuration of the cooling apparatus 10 will be described. FIG. 2 is a schematic diagram showing an embodiment of a detailed structure of the cooling apparatus 10. The cooling apparatus 10 of this embodiment includes a first refrigeration apparatus 51 in which a first refrigerant for performing heat exchange with the antifreeze liquid circulates, and a second refrigeration apparatus 52 in which a second refrigerant for performing heat exchange with the first refrigerant circulates. The first refrigeration apparatus 51 includes a first evaporator 61 configured to evaporate the first refrigerant in a liquid phase (i.e., a refrigerant liquid) to generate the first refrigerant in a gas phase (i.e., a refrigerant gas), a first compressor 62 configured to compress the first refrigerant in the gas phase, and a first condenser 64 configured to condense the compressed first refrigerant in the gas phase to generate the first refrigerant in the liquid phase. The first refrigeration apparatus 51 of this embodiment is a turbo refrigeration machine (i.e., centrifugal refrigeration machine) including the first compressor 62 which is a centrifugal compressor. The first evaporator 61, the first compressor 62, and the first condenser 64 are coupled by a first refrigerant line 66. The first refrigerant circulates among the first evaporator 61, the first compressor 62, and the first condenser 64 through the first refrigerant line 66.

The first refrigeration apparatus 51 further includes a first expansion valve 67 as a first expansion mechanism located between the first evaporator 61 and the first condenser 64. The first expansion valve 67 is attached to the first refrigerant line 66, and is disposed between the first evaporator 61 and the first condenser 64. The first refrigerant flowing from the first condenser 64 to the first evaporator 61 passes through the first expansion valve 67, so that pressure and temperature of the first refrigerant decrease. The first refrigerant that has passed through the first expansion valve 67 flows into the first evaporator 61.

The antifreeze-liquid circulation line 25 is coupled to the first evaporator 61, and heat exchange between the antifreeze liquid and the first refrigerant is performed in the first evaporator 61. As a result of this heat exchange, the antifreeze liquid is cooled to a low temperature (for example, −30° C. to −120° C.), while the first refrigerant is heated by the antifreeze liquid and evaporated into refrigerant gas. The cooled antifreeze liquid is delivered to the heat-exchanging units 8A to 8C through the antifreeze-liquid circulation line 25, and the refrigerant gas is delivered to the first compressor 62 through the first refrigerant line 66. The first compressor 62 compresses the refrigerant gas and sends the compressed refrigerant gas to the first condenser 64. In the first condenser 64, as described later, the refrigerant gas is condensed to form the refrigerant liquid.

The second refrigeration apparatus 52 includes a second evaporator 71 configured to evaporate a second refrigerant in a liquid phase (i.e., a refrigerant liquid) to generate a second refrigerant in a gas phase (i.e., a refrigerant gas), a second compressor 72 configured to compress the second refrigerant in the gas phase, and a second condenser 74 configured to condense the compressed second refrigerant in the gas phase to generate the second refrigerant in the liquid phase. The second refrigeration apparatus 52 of this embodiment is a turbo refrigeration machine (i.e., a centrifugal refrigeration machine) including the second compressor 72 which is a centrifugal compressor. The second evaporator 71, the second compressor 72, and the second condenser 74 are coupled by a second refrigerant line 76. The second refrigerant circulates among the second evaporator 71, the second compressor 72, and the second condenser 74 through the second refrigerant line 76.

The cooling apparatus 10 further includes an intermediate-medium circulation line 55 for circulating an intermediate medium between the first refrigeration apparatus 51 and the second refrigeration apparatus 52. The intermediate-medium circulation line 55 is coupled to the first refrigeration apparatus 51 and the second refrigeration apparatus 52. More specifically, the intermediate-medium circulation line 55 includes an intermediate-medium delivery line 55A configured to deliver the intermediate medium from the second evaporator 71 of the second refrigeration apparatus 52 to the first condenser 64 of the first refrigeration apparatus 51, and an intermediate-medium return line 55B configured to return the intermediate medium from the first condenser 64 of the first refrigeration apparatus 51 to the second evaporator 71 of the second refrigeration apparatus 52. One end of the intermediate-medium delivery line 55A is coupled to the first condenser 64, and the other end of the intermediate-medium delivery line 55A is coupled to the second evaporator 71. One end of the intermediate-medium return line 55B is coupled to the first condenser 64, and the other end of the intermediate-medium return line 55B is coupled to the second evaporator 71.

The intermediate medium circulates between the first condenser 64 of the first refrigeration apparatus 51 and the second evaporator 71 of the second refrigeration apparatus 52 through the intermediate-medium circulation line 55. The first refrigerant in the gas phase (i.e., the refrigerant gas) and the intermediate medium perform the heat exchange in the first condenser 64. As a result, the first refrigerant in the gas phase is cooled by the intermediate medium into the first refrigerant in the liquid phase (i.e., the refrigerant liquid). The intermediate medium is heated by the first refrigerant, so that the temperature of the intermediate medium rises.

The intermediate medium heated by the first refrigerant and the second refrigerant in the liquid phase (i.e., the refrigerant liquid) perform the heat exchange in the second evaporator 71. As a result, the second refrigerant in the liquid phase is heated by the intermediate medium into the second refrigerant in the gas phase (i.e., the refrigerant gas), while the intermediate medium is cooled by the second refrigerant and the temperature of the intermediate medium drops. The cooled intermediate medium is delivered to the first condenser 64 of the first refrigeration apparatus 51 through the intermediate-medium circulation line 55. The cooled intermediate medium and the first refrigerant perform the heat exchange in the first condenser 64. In this way, the intermediate medium circulates between the first condenser 64 of the first refrigeration apparatus 51 and the second evaporator 71 of the second refrigeration apparatus 52 through the intermediate-medium circulation line 55. The temperature of the intermediate medium flowing from the second evaporator 71 to the first condenser 64 is in a range of, for example, 0° C. to −80° C.

In the second evaporator 71, the second refrigerant is heated by the intermediate medium and evaporated into the refrigerant gas. This refrigerant gas is delivered to the second compressor 72 through the second refrigerant line 76. The second compressor 72 compresses the refrigerant gas and sends the compressed refrigerant gas to the second condenser 74. In the second condenser 74, heat exchange is performed between cooling water supplied from a cooling-water source (not shown) and the refrigerant gas (second refrigerant in the gas phase). As a result, the refrigerant gas is condensed into the refrigerant liquid.

As described above, the first refrigerant of the first refrigeration apparatus 51 and the second refrigerant of the second refrigeration apparatus 52 perform the heat exchange via the intermediate medium. The intermediate medium is a liquid of a type different from the first refrigerant and the second refrigerant. More specifically, the intermediate medium is a brine (or an antifreeze liquid), such as a perfluorocarbon (PFC) liquid or an ethylene glycol liquid. Therefore, the intermediate medium circulates as it is in the liquid phase in the intermediate-medium circulation line 55.

The brine (or the antifreeze liquid), which is easier to handle than the first refrigerant and the second refrigerant, can be used as the intermediate medium as long as the heat of the first refrigerant can be transferred to the second refrigerant. Therefore, a flexible and inexpensive pipe, such as a resin tube, can be used for the intermediate-medium circulation line 55. As a result, a manufacturing cost can be reduced. Moreover, a degree of freedom in the arrangement of the first refrigeration apparatus 51 and the second refrigeration apparatus 52 is increased.

The intermediate medium has a thermal capacity corresponding to its volume. Therefore, the intermediate medium functions as a thermal buffer between the first refrigerant and the second refrigerant. Generally, the temperature of the antifreeze liquid that has been used in the heat exchange in the heat-exchanging units 8A to 8C varies, and the temperature of the first refrigerant tends to fluctuate accordingly. Since the intermediate medium can absorb such fluctuations in the temperature of the first refrigerant, the operation of the cooling apparatus 10 can be stable. As a result, the cooling apparatus 10 can supply the antifreeze liquid having a stable temperature to the heat-exchanging units 8A to 8C.

The second refrigeration apparatus 52 further includes a second expansion valve 77 as a second expansion mechanism located between the second evaporator 71 and the second condenser 74. The second expansion valve 77 is attached to the second refrigerant line 76, and is disposed between the second evaporator 71 and the second condenser 74. The second refrigerant flowing from the second condenser 74 to the second evaporator 71 passes through the second expansion valve 77, so that pressure and temperature of the second refrigerant decrease. The second refrigerant that has passed through the second expansion valve 77 flows into the second evaporator 71.

According to this embodiment, the cooling apparatus 10 including the first refrigeration apparatus 51 and the second refrigeration apparatus 52 comprehensively cools the multiple processing chambers 2A to 2C, and has a function equivalent to that of a cooling apparatus including a dual refrigeration cycle by coupling the first refrigeration apparatus 51 and the second refrigeration apparatus 52 in series. Therefore, the antifreeze liquid can be cooled to a sufficiently low temperature. Furthermore, since the first refrigeration apparatus 51 and the second refrigeration apparatus 52 are configured as separate apparatuses, the first refrigeration apparatus 51 and the second refrigeration apparatus 52 can be installed in different locations. In this embodiment, the first refrigeration apparatus 51 is arranged in the sub-fab area, and the second refrigeration apparatus 52 is arranged outside the clean room and the sub-fab area. The pipe extending to the heat-exchanging units 8A to 8C can be shortened by arranging the first refrigeration apparatus 51 in the sub-fab area, so that heat loss can be reduced. The second refrigeration apparatus 52 is arranged outside the clean room and the sub-fab area, so that the installation space required in the clean room and the sub-fab area can be reduced.

Generally, lubricating oil is used for a bearing of the first compressor 62 of the first refrigeration apparatus 51. However, since a high cleanliness is required in the sub-fab area, the lubricating oil may not be allowed to be used for the first refrigeration apparatus 51 when the first refrigeration apparatus 51 is arranged in the sub-fab area. Furthermore, low noise is also required in the sub-fab area. Therefore, in this embodiment, the first compressor 62 of the first refrigeration apparatus 51 includes magnetic bearings as bearing devices in order to eliminate the use of the lubricating oil and achieve low noise.

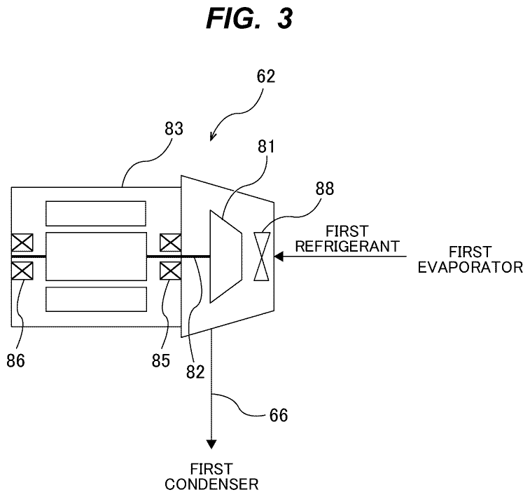

FIG. 3 is a schematic diagram showing an embodiment of a detailed structure of the first compressor 62 of the first refrigeration apparatus 51. The first compressor 62 of this embodiment is constituted of a single-stage centrifugal compressor. More specifically, the first compressor 62 includes a single-stage impeller 81, a rotor 82 rotatable together with the impeller 81, an electric motor 83 configured to rotate the impeller 81 and the rotor 82, and a magnetic bearing 85 and a magnetic bearing 86 rotatably support the rotor 82 in a non-contact manner. In this embodiment, the rotor 82 is a rotating shaft, and the impeller 81 is fixed to the rotating shaft. In one embodiment, the rotor 82 may be a combination of a rotating shaft and a gear. In one embodiment, the impeller 81 may be configured integrally with the rotor 82. The magnetic bearing 85 and the magnetic bearing 86 are arranged inside the electric motor 83, and are configured to magnetically levitate the rotor 82 to support the rotor 82 in a non-contact manner. In one embodiment, the first compressor 62 may be a multi-stage centrifugal compressor including multiple-stage impellers.

Guide vanes 88 are disposed in a suction port of the first compressor 62 to regulate a suction flow-rate of the first refrigerant to the impeller 81. The guide vanes 88 are located at a suction side of the impeller 81. The guide vanes 88 are disposed radially. Each guide vane 88 rotates synchronously with each other by a predetermined angle around its own axis, so that an opening degree of the guide vanes 88 is changed. The refrigerant gas of the first refrigerant delivered from the first evaporator 61 passes through the guide vanes 88, and is then pressurized by the rotating impeller 81. The pressurized refrigerant gas of the first refrigerant is delivered to the first condenser 64 through the first refrigerant line 66.

According to this embodiment, the first compressor 62 includes the magnetic bearing 85 and the magnetic bearing 86 that support the rotor 82 in a non-contact manner, so that the lubricating oil is not required for the first compressor 62. Therefore, the first compressor 62 can operate with high cleanliness and low noise. As a result, the first refrigeration apparatus 51 can be arranged in the sub-fab area where high cleanliness and low noise are required. In one embodiment, the second refrigeration apparatus 52 has the same configuration as that of the first refrigeration apparatus 51, and the second compressor 72 may include magnetic bearing(s) (not shown) configured to support a rotor (not shown) in a non-contact manner. In this case, the second refrigeration apparatus 52 may be arranged in the sub-fab area.

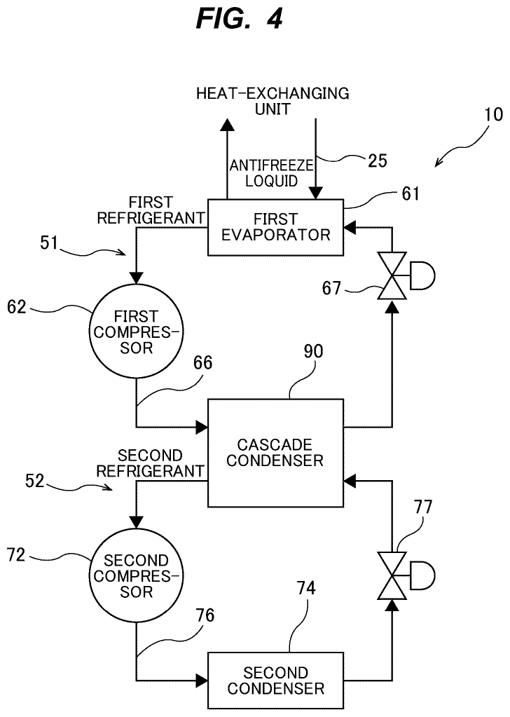

FIG. 4 is a schematic diagram showing another embodiment of a detailed structure of the cooling apparatus 10. The cooling apparatus 10 shown in FIG. 4 includes a dual refrigeration cycle using a first refrigerant and a second refrigerant having different boiling points. A boiling point of the first refrigerant is lower than that of the second refrigerant. Configurations and operations of this embodiment, which will not be particularly described, are the same as those of the embodiment described with reference to FIG. 2, and duplicated descriptions will be omitted.

The condenser of the first refrigeration apparatus 51 and the evaporator of the second refrigeration apparatus 52 are configured as a common cascade condenser 90. The cascade condenser 90 is a heat exchanger in which the condenser of the first refrigeration apparatus 51 serves as the evaporator of the second refrigeration apparatus 52. The cooling apparatus 10 having the dual refrigeration cycle may be installed in the sub-fab area if an installation space can be provided in the sub-fab area. Alternatively, the cooling apparatus 10 may be installed outside the sub-fab area if the installation space cannot be provided in the clean room or the sub-fab area.

In this embodiment, the intermediate-medium circulation line 55 described above is not provided. Both the first refrigerant line 66 of the first refrigeration apparatus 51 and the second refrigerant line 76 of the second refrigeration apparatus 52 are coupled to the cascade condenser 90. The first refrigerant circulating in the first refrigeration apparatus 51 and the second refrigerant circulating in the second refrigeration apparatus 52 flow through the cascade condenser 90, so that the heat exchange is performed between the first refrigerant and the second refrigerant in the cascade condenser 90.

According to this embodiment, the cooling apparatus 10 including the dual refrigeration cycle can cool the antifreeze liquid to a sufficiently low temperature required for cooling the multiple processing chambers 2A to 2C. In addition, since the cascade condenser 90 serves as the condenser of the first refrigeration apparatus 51 and the evaporator of the second refrigeration apparatus 52, the number of heat exchangers can be reduced. Therefore, the installation area of the cooling apparatus 10 can be reduced.

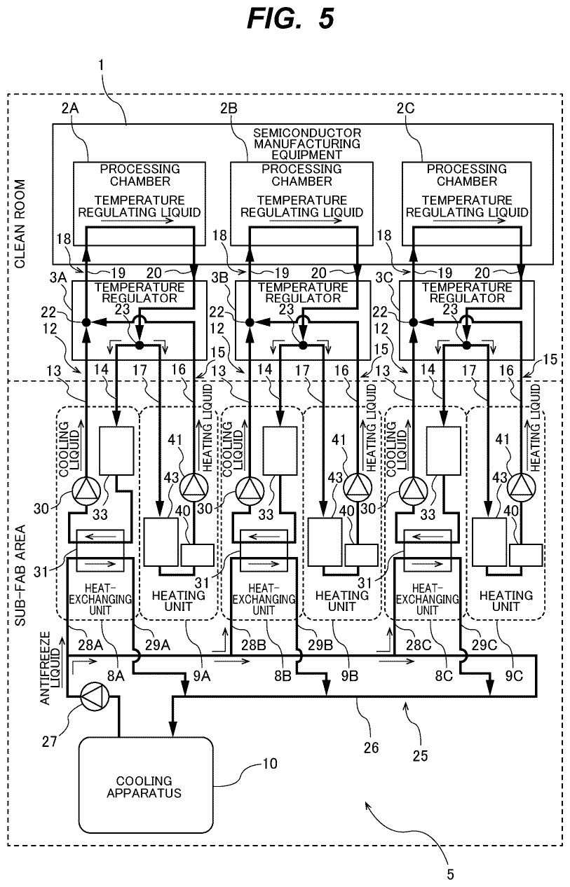

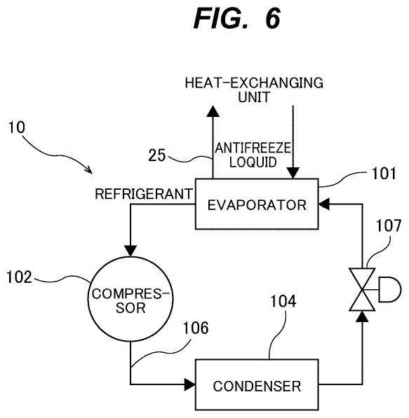

FIG. 5 is a schematic diagram showing another embodiment of the semiconductor manufacturing system including the cooling system 5. The cooling apparatus 10 of this embodiment is a single turbo refrigeration machine (centrifugal refrigeration machine), and the entire cooling apparatus 10 is arranged in the sub-fab area. FIG. 6 is a schematic diagram showing an embodiment of a detailed structure of the cooling apparatus 10 shown in FIG. 5. The cooling apparatus (turbo refrigeration machine) 10 includes an evaporator 101 configured to evaporate a refrigerant liquid to generate a refrigerant gas (refrigerant in a gas phase), a compressor 102 configured to compress the refrigerant gas, and a condenser 104 configured to condense the compressed refrigerant gas to generate a refrigerant liquid (refrigerant in a liquid phase). The evaporator 101, the compressor 102, and the condenser 104 are coupled by a refrigerant line 106. The refrigerant (refrigerant gas or refrigerant liquid) circulates among the evaporator 101, the compressor 102, and the condenser 104 through the refrigerant line 106.

The cooling apparatus (turbo refrigeration machine) 10 further includes an expansion valve 107 as an expansion mechanism located between the evaporator 101 and the condenser 104. The expansion valve 107 is attached to the refrigerant line 106. The refrigerant liquid flowing from the condenser 104 to the evaporator 101 passes through the expansion valve 107, so that pressure and temperature of the refrigerant liquid decrease. The refrigerant liquid that has passed through the expansion valve 107 flows into the evaporator 101.

The antifreeze-liquid circulation line 25 is coupled to the evaporator 101, and heat exchange is performed between the antifreeze liquid and the refrigerant liquid in the evaporator 101. As a result of this heat exchange, the antifreeze liquid is cooled to a low temperature (for example, −30° C. to −120° C.), while the refrigerant liquid is heated by the antifreeze liquid and evaporated into the refrigerant gas. The cooled antifreeze liquid is delivered to the heat-exchanging units 8A to 8C through the antifreeze-liquid circulation line 25, and the refrigerant gas is delivered to the compressor 102 through the refrigerant line 106. The compressor 102 compresses the refrigerant gas and sends the compressed refrigerant gas to the condenser 104. The condenser 104 condenses the refrigerant gas to generate the refrigerant liquid.

The compressor 102 of this embodiment includes magnetic bearing(s) as bearing device(s) in order to eliminate use of lubricating oil and achieve low noise. Details of the configuration of the compressor 102 are the same as those of the configuration of the first compressor 62 of the first refrigeration apparatus 51 described with reference to FIG. 3, and duplicated descriptions will be omitted.

The cooling apparatus (turbo refrigeration machine) 10 of this embodiment includes the centrifugal compressor 102 in which the magnetic bearings are used, so that a larger capacity and a higher efficiency than those of the conventional chiller including a positive displacement compressor can be achieved. In addition, the magnetic bearing(s) is used in the compressor 102, so that oil-free is achieved and recovery of oil is not required, and as a result, the efficiency can be further improved. Therefore, the cooling apparatus 10 can cool the antifreeze liquid to a sufficiently low temperature required for comprehensively cooling the multiple processing chambers 2A to 2C by itself. The cooling apparatus (turbo refrigeration machine) 10 of this embodiment is a large turbo refrigeration machine with a higher cooling capacity than that of the first refrigeration apparatus 51 and the second refrigeration apparatus 52 described with reference to FIG. 2. Therefore, the cooling apparatus (turbo refrigeration machine) 10 of this embodiment can cool the antifreeze liquid to a temperature of about −30° C. to −120° C. by itself.

In the embodiment shown in FIG. 5, the cooling apparatus (turbo refrigeration machine) 10 is arranged in the sub-fab area, while in one embodiment, the cooling apparatus (turbo refrigeration machine) 10 may be arranged outside the clean room and the sub-fab area.

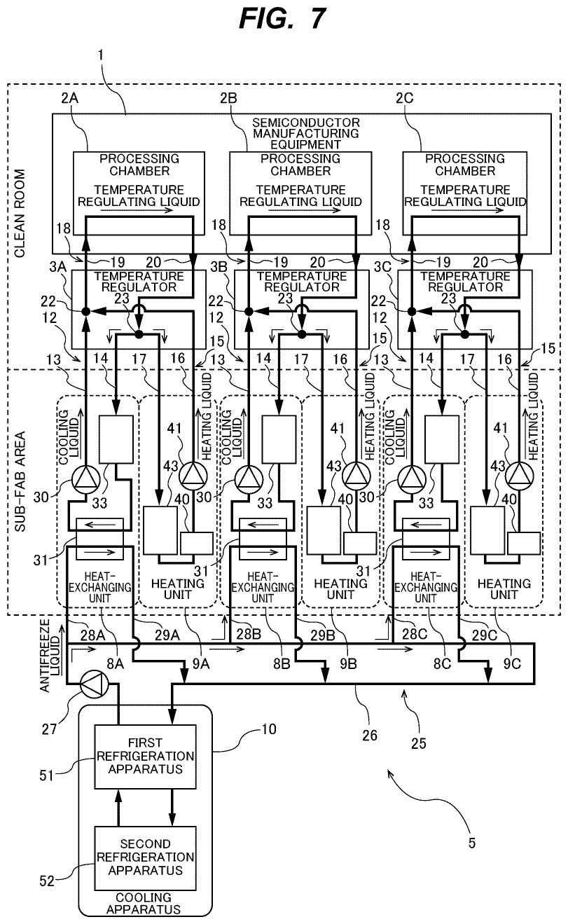

FIG. 7 is a schematic diagram showing still another embodiment of the semiconductor manufacturing system including the cooling system 5. In one embodiment, as shown in FIG. 7, the cooling apparatus 10 may be arranged outside the clean room and the sub-fab area. In this embodiment, the heat-exchanging units 8A to 8C and the heating units 9A to 9C are arranged in the sub-fab area. Such an arrangement of the cooling apparatus 10 can reduce the installation space required in the clean room and the sub-fab area. Any of the cooling apparatuses 10 described with reference to FIGS. 2 to 6 may be applied to the embodiment shown in FIG. 7.

The configuration of the cooling apparatus 10 is not limited to the embodiments described with reference to FIGS. 2 to 6 as long as the cooling apparatus 10 can cool the antifreeze liquid to a temperature of about −30° C. to −120° C.

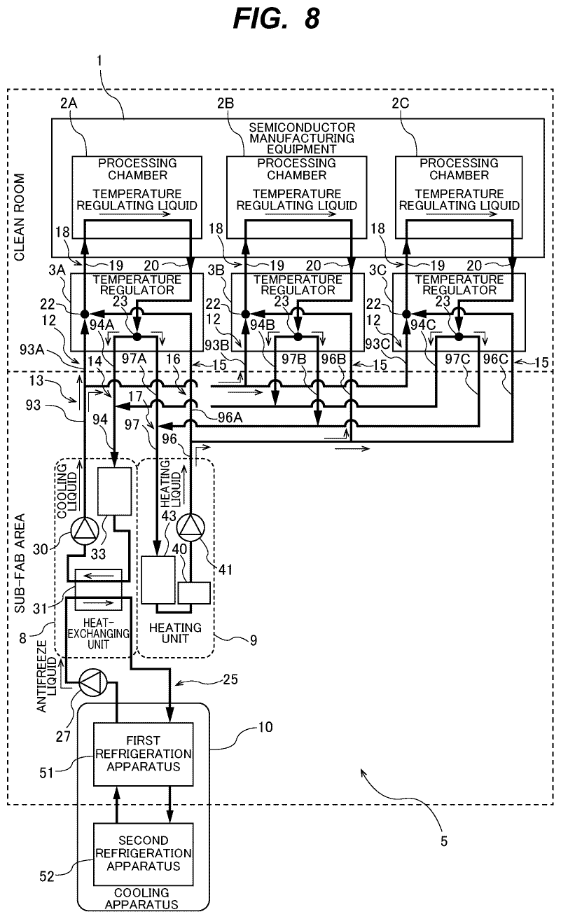

FIG. 8 is a schematic diagram showing still another embodiment of the semiconductor manufacturing system including the cooling system 5. Configurations and operations of this embodiment, which will not be particularly described, are the same as those of the embodiment described with reference to FIG. 1, and duplicated descriptions will be omitted. In the embodiment described with reference to FIG. 1, the cooling system 5 includes the multiple heat-exchanging units, the number of which is the same as the number of multiple processing chambers (three heat-exchanging units 8A to 8C, the same number as the three processing chambers 2A to 2C). In one embodiment, the cooling system 5 may include multiple heat-exchanging units, the number of which is less than the number of multiple processing chambers. In the embodiment shown in FIG. 8, the cooling system 5 includes a single heat-exchanging unit 8.

Similarly, in the embodiment described with reference to FIG. 1, the cooling system 5 includes the multiple heating units, the number of which is the same as the number of multiple processing chambers (three heating units 9A to 9C, the number of which is the same number as the three processing chambers 2A to 2C). In one embodiment, the cooling system 5 may include multiple heating units, the number of which is less than the number of multiple processing chambers. In the embodiment shown in FIG. 8, the cooling system 5 includes a single heating unit 9. Configurations of the heat-exchanging unit 8 and the heating unit 9 are basically the same as the configurations of the heat-exchanging unit 8A and the heating unit 9A described above, and duplicated descriptions will be omitted.

In this embodiment, the antifreeze-liquid circulation line 25 of the cooling system 5 extends between the heat-exchanging unit 8 and the cooling apparatus 10. The antifreeze-liquid pump 27 is disposed in the antifreeze-liquid circulation line 25, and is configured to circulate the antifreeze liquid between the cooling apparatus 10 and the heat-exchanging unit 8. The antifreeze liquid supplied from the cooling apparatus 10 flows through the antifreeze-liquid circulation line 25, is introduced to the heat exchanger 31 of the heat-exchanging unit 8, and performs heat exchange with the cooling liquid. The antifreeze liquid heated by passing through the heat exchanger 31 is returned the cooling apparatus 10 through the antifreeze-liquid circulation line 25.

The cooling liquid generated by the heat-exchanging unit 8 is supplied to the temperature regulators 3A to 3C through the cooling-liquid supply line 13. More specifically, the cooling-liquid supply line 13 includes a trunk cooling-liquid supply line 93 coupled to the heat exchanger 31 of the heat-exchanging unit 8, and a first cooling-liquid supply line 93A, a second cooling-liquid supply line 93B, and a third cooling-liquid supply line 93C branching off from the trunk cooling-liquid supply line 93. The first cooling-liquid supply line 93A extends between the trunk cooling-liquid supply line 93 and the temperature regulator 3A. The second cooling-liquid supply line 93B extends between the trunk cooling-liquid supply line 93 and the temperature regulator 3B. The third cooling-liquid supply line 93C extends between the trunk cooling-liquid supply line 93 and the temperature regulator 3C. The cooling-liquid pump 30 is coupled to the trunk cooling-liquid supply line 93.

The cooling liquid generated by the heat-exchanging unit 8 flows through the trunk cooling-liquid supply line 93, and branches off into the first cooling-liquid supply line 93A, the second cooling-liquid supply line 93B, and the third cooling-liquid supply line 93C. The cooling liquid flowing through the first cooling-liquid supply line 93A is mixed with the heating liquid generated by the heating unit 9 in the mixing section 22 of the temperature regulator 3A, and is supplied to the processing chamber 2A. Similarly, the cooling liquid flowing through the second cooling-liquid supply line 93B is mixed with the heating liquid generated by the heating unit 9 in the mixing section 22 of the temperature regulator 3B, and is supplied to the processing chamber 2B. The cooling liquid flowing through the third cooling-liquid supply line 93C is mixed with the heating liquid generated by the heating unit 9 in the mixing section 22 of the temperature regulator 3C, and is supplied to the processing chamber 2C. In this way, the heat-exchanging unit 8 supplies the cooling liquid to the processing chambers 2A to 2C via the temperature regulators 3A to 3C.

The heating liquid generated by the heating unit 9 is supplied to the temperature regulators 3A to 3C through the heating-liquid supply line 16. More specifically, the heating-liquid supply line 16 includes a trunk heating-liquid supply line 96 coupled to the heating apparatus 40 of the heating unit 9, and a first heating-liquid supply line 96A, a second heating-liquid supply line 96B, and a third heating-liquid supply line 96C branching off from the trunk heating-liquid supply line 96. The first heating-liquid supply line 96A extends between the trunk heating-liquid supply line 96 and the temperature regulator 3A. The second heating-liquid supply line 96B extends between the trunk heating-liquid supply line 96 and the temperature regulator 3B. The third heating-liquid supply line 96C extends between the trunk heating-liquid supply line 96 and the temperature regulator 3C. The heating-liquid pump 41 is coupled to the trunk heating-liquid supply line 96.

The heating liquid generated by the heating unit 9 flows through the trunk heating-liquid supply line 96, and branches off into the first heating-liquid supply line 96A, the second heating-liquid supply line 96B, and the third heating-liquid supply line 96C. The heating liquid flowing through the first heating-liquid supply line 96A is mixed with the cooling liquid generated by the heat-exchanging unit 8 in the mixing section 22 of the temperature regulator 3A, and is supplied to the processing chamber 2A. Similarly, the heating liquid flowing through the second heating-liquid supply line 96B is mixed with the cooling liquid generated by the heat-exchanging unit 8 in the mixing section 22 of the temperature regulator 3B, and is supplied to the processing chamber 2B. The heating liquid flowing through the third heating-liquid supply line 96C is mixed with the cooling liquid generated by the heat-exchanging unit 8 in the mixing section 22 of the temperature regulator 3C, and is supplied to the processing chamber 2C. In this way, the heating unit 9 supplies the heating liquid to the processing chambers 2A to 2C via the temperature regulators 3A to 3C.

The temperature-regulating liquid that has passed through the processing chambers 2A to 2C flows through the temperature-regulating-liquid return lines 20, and is distributed to the cooling-liquid return line 14 and the heating-liquid return line 17 at the distribution sections 23 of the temperature regulators 3A to 3C. Specifically, a part of the temperature-regulating liquid is returned as the cooling liquid to the heat-exchanging unit 8 through the cooling-liquid return line 14, and the other part of the temperature-regulating liquid is returned as the heating liquid to the heating unit 9 through the heating-liquid return line 17. The cooling-liquid return line 14 includes a trunk cooling-liquid return line 94 coupled to the heat-exchanging unit 8, and a first cooling-liquid return line 94A, a second cooling-liquid return line 94B, and a third cooling-liquid return line 94C merged into the trunk cooling-liquid return line 94. The first cooling-liquid return line 94A extends between the trunk cooling-liquid return line 94 and the temperature regulator 3A. The second cooling-liquid return line 94B extends between the trunk cooling-liquid return line 94 and the temperature regulator 3B. The third cooling-liquid return line 94C extends between the trunk cooling-liquid return line 94 and the temperature regulator 3C.

The cooling liquid that has passed through the processing chamber 2A is distributed at the distribution section 23 of the temperature regulator 3A to flow through the first cooling-liquid return line 94A, and is merged into the trunk cooling-liquid return line 94. The cooling liquid that has passed through the processing chamber 2B is distributed at the distribution section 23 of the temperature regulator 3B to flow through the second cooling-liquid return line 94B, and is merged into the trunk cooling-liquid return line 94. The cooling liquid that has passed through the processing chamber 2C is distributed at the distribution section 23 of the temperature regulator 3C to flow through the third cooling-liquid return line 94C, and is merged into the trunk cooling-liquid return line 94. The cooling liquid flowing through the trunk cooling-liquid return line 94 is returned to the heat-exchanging unit 8.

The heating-liquid return line 17 includes a trunk heating-liquid return line 97 coupled to the heating unit 9, and a first heating-liquid return line 97A, a second heating-liquid return line 97B, and a third heating-liquid return line 97C merged into the trunk heating-liquid return line 97. The first heating-liquid return line 97A extends between the trunk heating-liquid return line 97 and the temperature regulator 3A. The second heating-liquid return line 97B extends between the trunk heating-liquid return line 97 and the temperature regulator 3B. The third heating-liquid return line 97C extends between the trunk heating-liquid return line 97 and the temperature regulator 3C.

The heating liquid that has passed through the processing chamber 2A is distributed at the distribution section 23 of the temperature regulator 3A to flow through the first heating-liquid return line 97A, and is merged into the trunk heating-liquid return line 97. The heating liquid that has passed through the processing chamber 2B is distributed at the distribution section 23 of the temperature regulator 3B to flow through the second heating-liquid return line 97B, and is merged into the trunk heating-liquid return line 97. The heating liquid that has passed through the processing chamber 2C is distributed at the distribution section 23 of the temperature regulator 3C to flow through the third heating-liquid return line 97C, and is merged into the trunk heating-liquid return line 97. The heating liquid flowing through the trunk heating-liquid return line 97 is returned to the heating unit 9.

In this manner, the cooling liquid circulates among the heat-exchanging unit 8, the temperature regulators 3A to 3C, and the processing chambers 2A to 2C through the cooling-liquid lines 12 and the temperature-regulating-liquid lines 18. The heating liquid circulates among the heating unit 9, the temperature regulators 3A to 3C, and the processing chambers 2A to 2C through the heating-liquid lined 15 and the temperature-regulating-liquid lines 18.

According to this embodiment, the installation space required for the heat-exchanging unit 8 itself can be reduced, and the number of pipes coupled to the heat-exchanging unit 8 can also be reduced. As a result, the installation space required in the sub-fab area can be further reduced. In addition, the cooling liquid returned to the heat-exchanging unit 8 through the cooling-liquid return line 14 is stored in the cooling-side buffer tank 33. Since the single cooling-side buffer tank 33 is provided, even if variations in temperature of the cooling liquid returned from the processing chambers 2A to 2C occur, the cooling-side buffer tank 33 functions as a thermal buffer to make the temperature of the cooling liquid uniform. As a result, heat exchange conditions in the heat exchanger 31 can be improved.

Furthermore, according to this embodiment, the installation space required for the heating unit 9 itself can be reduced, and the number of pipes coupled to the heating unit 9 can also be reduced. As a result, the installation space required in the sub-fab area can be further reduced. In addition, a time required to heat each of the processing chambers 2A to 2C during the processing cycle performed in each of the processing chamber 2A to 2C is relatively short. Therefore, the heating apparatus 40 with a low heating capacity (i.e., low power consumption) can be used to heat the multiple processing chambers 2A to 2C by adjusting the processing cycles of the processing chambers 2A to 2C so as not to overlap the heating times of the multiple processing chambers 2A to 2C. In addition, the heating liquid returned to the heating unit 9 through the heating-liquid return line 17 is stored in the heating-side buffer tank 43. Since the single heating-side buffer tank 43 is provided, even if variations in temperature of the heating liquid returned from the processing chambers 2A to 2C occur, the heating-side buffer tank 43 functions as a thermal buffer to make the temperature of the heating liquid uniform. As a result, fluctuations in the temperature of the heating liquid flowing through the heating apparatus 40 can be reduced.

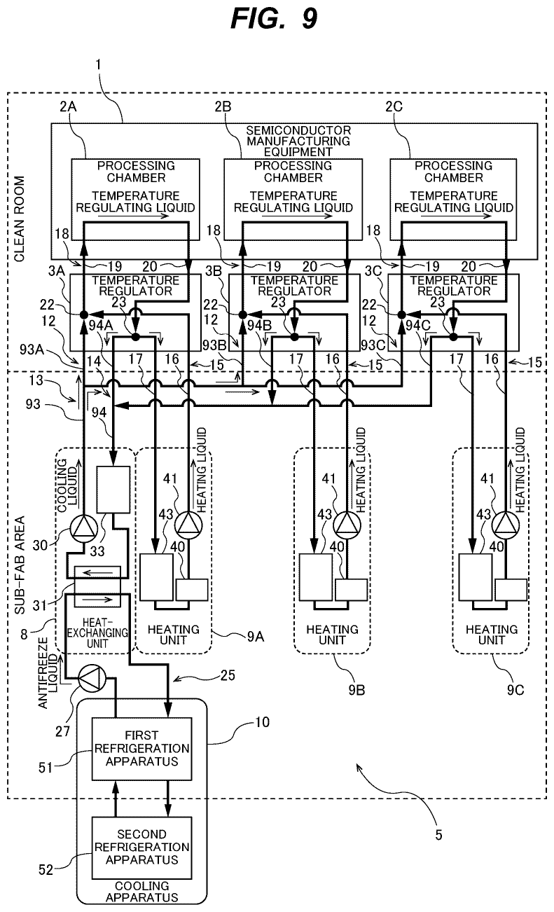

In one embodiment, as shown in FIG. 9, the cooling system 5 may include a single heat-exchanging unit 8 and multiple heating units 9A to 9C. Configurations of the single heat-exchanging unit 8, the cooling-liquid supply line 13, and the cooling-liquid return line 14 are the same as those of the embodiment described with reference to FIG. 8, and duplicated descriptions will be omitted. Configurations of the cooling apparatus 10, the multiple heating units 9A to 9C, the heating-liquid supply line 16, and the heating-liquid return line 17 are the same as those of the embodiment described with reference to FIG. 1, and duplicated descriptions will be omitted.

According to this embodiment, the heating units 9A to 9C can operate independently according to the processing cycles in the multiple processing chambers 2A to 2C. Furthermore, according to this embodiment, the installation space required for the heat-exchanging unit 8 itself can be reduced, and the number of pipes coupled to the heat-exchanging unit 8 can also be reduced. As a result, the installation space required in the sub-fab area can be further reduced. In addition, since the single cooling-side buffer tank 33 is provided, even if variations in temperature of the cooling liquid returned from the processing chambers 2A to 2C occur, the cooling-side buffer tank 33 makes the temperature of the cooling liquid uniform. As a result, heat exchange conditions in the heat exchanger 31 can be improved.

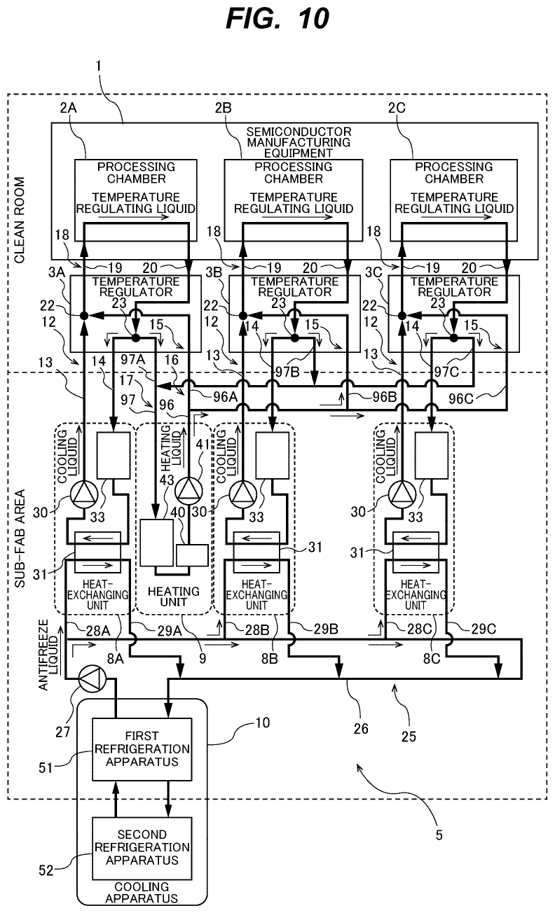

In one embodiment, as shown in FIG. 10, the cooling system 5 may include multiple heat-exchanging units 8A to 8C and a single heating unit 9. Configurations of the cooling apparatus 10, the multiple heat-exchanging units 8A to 8C, the cooling-liquid supply line 13, and the cooling-liquid return line 14 are the same as those in the embodiment described with reference to FIG. 1, and duplicated descriptions will be omitted. Configurations of the single heating unit 9, the heating-liquid supply line 16, and the heating-liquid return line 17 are the same as those in the embodiment described with reference to FIG. 8, and duplicated descriptions will be omitted.

According to this embodiment, the heat-exchanging units 8A to 8C can operate independently according to the processing cycles in the multiple processing chambers 2A to 2C. Furthermore, according to this embodiment, the installation space required for the heating unit 9 itself can be reduced, and the number of pipes coupled to the heating unit 9 can also be reduced. As a result, the installation space required in the sub-fab area can be further reduced. In addition, a time required to heat each of the processing chambers 2A to 2C during the processing cycle performed in each of the processing chamber 2A to 2C is relatively short. Therefore, the heating apparatus 40 with a low heating capacity (i.e., low power consumption) can be used to heat the multiple processing chambers 2A to 2C by adjusting the processing cycles of the processing chambers 2A to 2C so as not to overlap the heating times of the multiple processing chambers 2A to 2C.

The cooling apparatuses 10 described with reference to FIGS. 4 to 7 may be applied to the embodiment shown in FIGS. 9 and 10.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### INDUSTRIAL APPLICABILITY

The present invention is applicable to a cooling system for use in cooling of semiconductor manufacturing equipment, such as etching equipment.

### REFERENCE SIGNS LIST

1 semiconductor manufacturing equipment
2A to 2C processing chamber
3A to 3C temperature regulator
5 cooling system
8, 8A, 8B, 8C heat-exchanging unit
9, 9A, 9B, 9C heating unit
10 cooling apparatus
12 cooling-liquid line
13 cooling-liquid supply line
14 cooling-liquid return line
15 heating-liquid line
16 heating-liquid supply line
17 heating-liquid return line
18 temperature-regulating-liquid line
19 temperature-regulating-liquid supply line
20 temperature-regulating-liquid return line
22 mixing section
23 distribution section
25 antifreeze-liquid circulation line
26 trunk circulation line
27 antifreeze-liquid pump
28A first branch supply line
29A first branch return line
28B second branch supply line
29B second branch return line
28C third branch supply line
29C third branch return line
30 cooling-liquid pump
31 heat exchanger
33 cooling-side buffer tank
40 heating apparatus
41 heating-liquid pump
43 heating-side buffer tank
51 first refrigeration apparatus
52 second refrigeration apparatus
55 intermediate-medium circulation line
61 first evaporator
62 first compressor
64 first condenser
66 first refrigerant line
67 first expansion valve
71 second evaporator
72 second compressor
74 second condenser
76 second refrigerant line
77 second expansion valve
81 impeller
82 rotor
83 electric motor
85,86 magnetic bearing
88 guide vane
90 cascade condenser
93 trunk cooling-liquid supply line
93A first cooling-liquid supply line
93B second cooling-liquid supply line
93C third cooling-liquid supply line
94 trunk cooling-liquid return line
94A first cooling-liquid return line
94B second cooling-liquid return line
94C third cooling-liquid return line
96 trunk heating-liquid supply line
96A first heating-liquid supply line
96B second heating-liquid supply line
96C third heating-liquid supply line
97 trunk heating-liquid return line
97A first heating-liquid return line
97B second heating-liquid return line
97C third heating-liquid return line
101 evaporator
102 compressor
104 condenser
106 refrigerant line
107 expansion valve
501 etching equipment
502 processing chamber
505 chiller
506 evaporator
507 compressor
508 condenser
510 large refrigeration machine

1. A cooling system for cooling multiple processing chambers for use in semiconductor manufacturing process, comprising:
at least one heat-exchanging unit configured to generate a cooling liquid for cooling the multiple processing chambers arranged in a clean room and supply the cooling liquid to the multiple processing chambers;
a cooling apparatus configured to cool an antifreeze liquid;
an antifreeze-liquid circulation line extending between the heat-exchanging unit and the cooling apparatus; and
an antifreeze-liquid pump configured to circulate the antifreeze liquid in the antifreeze-liquid circulation line, wherein the heat-exchanging unit includes:
a cooling-liquid pump configured to circulate the cooling liquid through the multiple processing chambers;
a heat exchanger configured to perform heat exchange between the cooling liquid and the antifreeze liquid; and
a cooling-side buffer tank arranged upstream of the heat exchanger in a circulating direction of the cooling liquid.

2. The cooling system according to claim 1, wherein the cooling apparatus includes:
a first refrigeration apparatus configured to circulate a first refrigerant for performing heat exchange with the antifreeze liquid;
a second refrigeration apparatus configured to circulate a second refrigerant for performing heat exchange with the first refrigerant; and
an intermediate-medium circulation line configured to circulate an intermediate medium between the first refrigeration apparatus and the second refrigeration apparatus.

3. The cooling system according to claim 1, wherein the cooling apparatus comprises a refrigeration machine including a dual refrigeration cycle.

4. The cooling system according to claim 1, wherein the heat-exchanging unit is arranged in a sub-fab area located under the clean room.

5. The cooling system according to claim 2, wherein
the first refrigeration apparatus is arranged in a sub-fab area located under the clean room, and
the second refrigeration apparatus is arranged outside the clean room and the sub-fab area.

6. The cooling system according to claim 5, wherein
the first refrigeration apparatus comprises a turbo refrigeration machine including a compressor configured to compress refrigerant gas, and
the compressor includes:
an impeller;
a rotor rotatable together with the impeller; and
a magnetic bearing configured to rotatably support the rotor in a non-contact manner.

7. The cooling system according to claim 1, wherein
the cooling apparatus comprises a turbo refrigeration machine including a compressor configured to compress refrigerant gas, and
the compressor includes:
an impeller;
a rotor rotatable together with the impeller; and
a magnetic bearing configured to rotatably support the rotor in a non-contact manner.

8. The cooling system according to claim 1, wherein the cooling apparatus is arranged outside the clean room and a sub-fab area located under the clean room.

9. The cooling system according to claim 1, wherein the heat-exchanging unit is removable from the cooling system.

10. The cooling system according to claim 1, wherein the at least one heat-exchanging unit comprises multiple heat-exchanging units, and the number of multiple heat-exchanging units is the same as the number of multiple processing chambers.

11. The cooling system according to claim 1, wherein the at least one heat-exchanging unit comprises multiple heat-exchanging units, and the number of multiple heat-exchanging units is less than the number of multiple processing chambers.

12. The cooling system according to claim 1, wherein the at least one heat-exchanging unit comprises a single heat-exchanging unit.

13. The cooling system according to claim 1, further comprising:
at least one heating unit configured to generate a heating liquid for heating the multiple processing chambers and supply the heating liquid to the multiple processing chambers,
wherein the heating unit includes:
a heating apparatus configured to heat the heating liquid;
a heating-liquid pump configured to circulate the heating liquid through the multiple processing chambers; and
a heating-side buffer tank arranged upstream of the heating apparatus in a circulating direction of the heating liquid.

14. The cooling system according to claim 13, wherein the heating unit is removable from the cooling system.

15. The cooling system according to claim 13, wherein the at least one heating unit comprises multiple heating units, and the number of multiple heating units is the same as the number of multiple processing chambers.

16. The cooling system according to claim 13, wherein the at least one heating unit comprises multiple heating units, and the number of multiple heating units is less than the number of multiple processing chambers.

17. The cooling system according to claim 13, wherein the at least one heating unit comprises a single heating unit.

18. A semiconductor manufacturing system comprising:
semiconductor manufacturing equipment having multiple processing chambers for performing a semiconductor manufacturing process;
a temperature regulator configured to regulate temperature of the multiple processing chambers;
a cooling-liquid line extending between the temperature regulator and a heat-exchanging unit;
a temperature-regulating-liquid line extending between the temperature regulator and the multiple processing chambers; and
the cooling system according to claim 1 for cooling the multiple processing chambers.
